(19) United States
(12) Patent Application Publication
(10) Pub. No.: US 2007/0201596 A1
(43) Pub. Date: Aug. 30, 2007

(54) Clock synchronization using early clock

(76) Inventors: John P. Flowers, San Jose, CA (US); Raymond Yeung, San Jose, CA (US); Janet Love Yun, Santa Clara, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/363,851

(22) Filed: Feb. 28, 2006

(51) Int. Cl. H03D 3/24

(52) U.S. Cl. 375/376

(57) ABSTRACT

A method and apparatus for synchronizing clocks using an early clock are described.

### BACKGROUND

Often, it is necessary to synchronize the clocking functions of multiple electronic components. For example, in measurement and testing systems and apparatuses, there are often multiple circuit boards required to carry out the measurement or test. These circuit boards are designed to perform the measurement or test at specified times, requiring accuracy of the clocking function of each circuit board. In addition, it is often necessary for the clocking function of one circuit board to be substantially synchronized with the clocking function of another circuit board.

One type of measurement apparatus that may rely on synchronized clock functions of multiple circuit boards is an interferometer. As is known, interferometers may be used to precisely measure displacement. In the semiconductor processing industry, interferometers may be used to accurately determine displacement of photolithographic equipment, for example. One circuit board of the interferometer may be adapted to garner measurement samples in one direction in one location and another circuit board may be adapted to garner measurements in a perpendicular direction at the same location.

To ensure measurement accuracy, these measurements taken in two directions should be taken during substantially the same time period, referred to as a ‘sample aperture.’ If the measurement samples are not taken during substantially the same sample aperture, the measurement data may be inaccurate do to interim displacement of components being measured. Accordingly, the synchronization of clocking functions of the circuit boards to within acceptable limits is useful in providing accurate interferometric measurements.

In addition to acquiring data at substantially the same sample aperture, it is also useful to adjust the synchronization of the clock functions on multiple electronic components. For example, the circuit boards of the interferometer are connected using electrical cables with connectors. If one of these connectors is not properly fastened, additional signal transmission delay may result. This may cause synchronized clocking functions to become unsynchronized.

Previous attempts to address synchronizing clock functions on circuit boards in measurement systems include providing a measurement signal to multiple circuit boards. Unfortunately, the distributed measurement signals are subject to interference and noise, resulting in unacceptable measurement data. Other previous attempts require exceptional accuracy of the length of cables connecting the circuit boards.

There is a need, therefore, for a method and apparatus for synchronizing clocks of electronic components and circuit boards.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a simplified block diagram of electrical components including clock synchronization apparatuses in accordance with an example embodiment.

FIG. 2 is a simplified block diagram of a clock synchronization apparatus in accordance with an example embodiment.

FIG. 3A is a simplified schematic diagram of a phase detector/balancer (PDB) circuit in accordance with an example embodiment.

FIGS. 3B-3D are timing diagrams including clock signals in a sequence of synchronizing clock functions of electronic components in accordance with an example embodiment.

FIG. 4 is a simplified block diagram of a clock synchronization circuit in accordance with an example embodiment.

FIG. 5A is a simplified block diagram of a clock synchronization apparatus in accordance with an example embodiment.

FIG. 5B is a simplified schematic diagram of the error detection circuit in accordance to an example embodiment.

FIG. 6 is a simplified block diagram of an apparatus useful in calibration of a jitter or skew measurement apparatus in accordance with an example embodiment.

### DETAILED DESCRIPTION

In the following detailed description, for purposes of explanation and not limitation, specific details are set forth in order to provide a thorough understanding of example embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the example embodiments. Such methods and apparati are clearly within the scope of the present teachings.

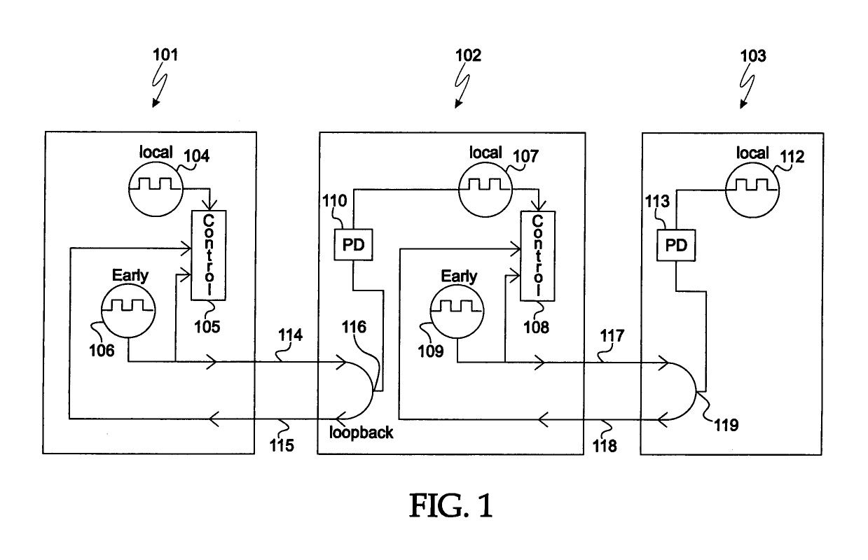

FIG. 1 is a simplified block diagram of a first electronic component 101, a second electronic component 102 and a third electronic component 103 including clock synchronization apparatuses in accordance with an example embodiment. For illustrative purposes, the electronic components 101-103 are circuit boards that require synchronization of clock functions to within an acceptable limit. In the interest of simplicity of description, the electronic components 101-103 are referred to as circuit boards. However, it is emphasized that the clock synchronization method and apparatuses of the example embodiments may be implemented other electronic components and applications requiring synchronization of clocking functions. Moreover, many aspects of the present teachings may be described using three circuit boards. Notably, there may be more or fewer circuit boards having features similar to those described in connections with circuit boards 101-103.

In the present embodiment, the circuit boards 101-103 are provided in a ‘daisy chain’ fashion, with each circuit board (excepting the final one in the chain) adapted to synchronize the clocking function of the next circuit board. In certain embodiments, the are circuit boards 101-103 are components of a measurement apparatus, such as an interferometer and are used to garner measurements from a component or system (not shown) under measure. As is known, it is often beneficial for the measurements to be garnered at substantially the same sample aperture. In other embodiments, the circuit boards 101-103 are components of a communication system, such as a data transmission system that requires the substantial synchronization of the clock functions of multiple boards. It is contemplated that embodiments of the present teachings may be implemented in a variety of applications requiring substantial synchronization of the clock functions of multiple boards/components.

The first circuit board 101 includes a first local clock 104, a first controller 105 and a first early clock 106. The second circuit board 102 includes a second local clock 107, a second controller 108, a second early clock 109 and a phase detector 110. The third circuit board 103, being the terminus of the chain in the present example embodiment, includes a third local clock 112 and a second phase detector 113. However, the third circuit 103 may include a controller and an early clock, which are not engaged to provide a synchronization function.

In the example embodiment, the first circuit board 101 is adapted to substantially synchronize in phase and frequency the first local clock 104 to the second local clock 107 of the second circuit board 102. Similarly, the second circuit board 102 is adapted to substantially synchronize in phase and frequency the second local clock 107 to the third local clock 112 of the third circuit board. In this manner, because the first local clock 104 is substantially synchronized to the second local clock 107 and the second local clock 107 is substantially synchronized to the third local clock 112, the clock functions of all three boards are substantially synchronized to one another. As explained more fully herein, and among other factors, the term ‘substantially synchronized’ means synchronized to within the limits of a transfer function of a difference amplifier provided in the controllers 105, 108.

The first circuit board 101 includes a first delay path 114 and a second delay path 115 (collectively a ‘delay path’). The delay paths 114, 115 include the propagation delay of transmission lines, such as electrical cables that connect the first and second boards 101, 102 electrically. The delay paths 114, 115 may also include propagation delay from active and passive electrical components (not shown) such as splitters and filters, to name only a few. Regardless of the components used, the propagation delay of first delay path 114 is substantially the same as that of second delay path 115. Finally, the second delay path 115 may be referred to as the return delay path and includes a return clock signal or return signal.

At a midpoint 116 of the delay path, the clock signal provided to the second circuit board 102 is substantially synchronized with the first local clock 104. As described more fully herein, the early clock 106 is adjusted by the controller 105 to lead the local clock 104 in time (or phase) by a duration that is substantially the same as a lag in time (or phase) of the local clock 104 to the returned clock signal. By ensuring the early clock 106 leads the local clock 104 by the same duration that the returned clock signal lags the local clock 104, the clock signal at the midpoint 116 of the delay path is substantially synchronized with the local clock 104. Because the clock signal at midpoint 116 is used to provide the clock function of the second circuit board 102, the clock functions of the first and second circuit boards 101, 102 are substantially synchronized is phase and frequency.

In a similar fashion, the second circuit board 102 includes a third delay path 117 and a fourth delay path 118 (collectively a delay path). Like the delay paths 114, 115, delays paths 117, 118 provide substantially the same propagation delay. The delay path provided by delay paths 117, 118 has a midpoint 119. Like midpoint 116, the clock signal at the midpoint 119 of the delay path is substantially synchronized with the local clock 107. Because the clock signal at midpoint 119 is used to provide the clock function of the third circuit board 103, the clock functions of the second and third circuit boards 102, 103 are substantially synchronized is phase and frequency. Accordingly, it follows that the clock functions of the first circuit board 101 and the third circuit board 103 are substantially synchronized.

The phase detectors 110, 113 and the local oscillators 107,112 are optional. In particular, these components are useful in reducing the ill-effects of signal noise and electromagnetic radiation. Accordingly, the clock signals at the midpoints 116, 119, which are synchronized to the local clock 104, may be used to provide the ‘local clock’ of circuit boards 102, 103, respectively. In an embodiment, the signal at midpoint 116 may be input to the controller 108 and used to synchronize the signal at midpoint 119; and the signal at midpoint 119 may be used as the local clock directly.

From the above description, it can be appreciated that the first circuit board 101 provides a ‘master’ clock signal to the second circuit board 102, which in turn provides a ‘master’ clock signal to the third circuit board 103. The third circuit board 103 is the terminus board and provides no further signal in the present embodiment. Accordingly, the first circuit board 101 may be considered the master board and the second and third circuit boards 102, 103 may be considered slave boards. However, in a specific embodiment, the measurement apparatus or other apparatus of the present teachings may include a plurality of circuit boards each including the components for clock synchronization of first circuit board 101. This allows for ease of manufacture and interchangeability of the circuit boards.

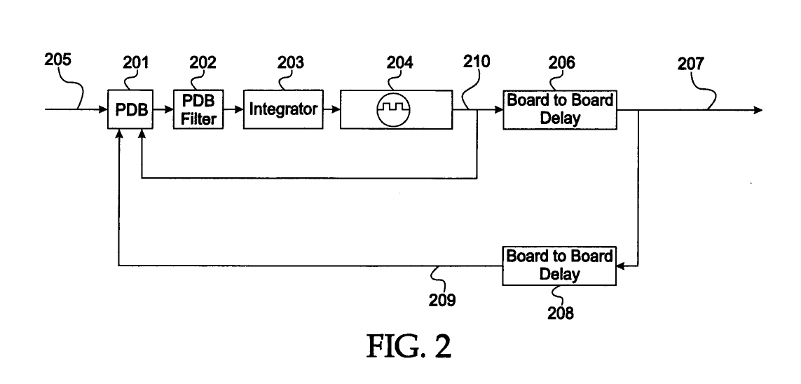

FIG. 2 is a simplified block diagram of a clock synchronization apparatus in accordance with an example embodiment. Certain components described in connection with the example embodiment of FIG. 1 are described more fully in connection with the apparatus. The apparatus may be disposed on an electronic component and is adapted to synchronize a local clock on the component with a local clock on another electronic component. In specific embodiments, the apparatus may be disposed on circuit boards in measurement apparatuses such as described in connection with FIG. 1.

The apparatus includes a phase detector balancer (PDB) circuit 201 and filter 202 and an integrator 203. Together, the PDB circuit 201, the filter 202 and the integrator 203 comprise controllers 105, 108. The apparatus also includes an oscillator 204. In an embodiment, the oscillator 204 is a voltage controlled crystal oscillator (VCXO) or other suitable clocking device. The PDB 201 receives an input clock signal 205 from a first local clock. The input clock signal 205 may be from the first local clock (104), which is a VCXO or similar clocking device. Alternatively, the input clock signal 205 may be the clock signal at the midpoint (e.g., midpoints 116, 119) of the delay path. Illustratively, the input clock signal 205 is a square wave signal having a frequency of approximately 80.0 MHz.

The PDB 201 provides an output signal to the filter 202, which is a known phase lock loop (PLL or loop) filter. The output of the loop filter 202 is provided to the integrator 203. As described more fully herein, the integrator 203 provides a voltage to the oscillator resulting in a desired output signal phase and frequency.

In the present example embodiment, the oscillator 204 functions as the early clock (e.g., early clock 106, 109) and is useful in providing synchronization of a local clock to a clock signal at the midpoint of the delay path. This clock signal at the midpoint (e.g., midpoints 116, 119) may be used to phase lock a local clock (e.g. local clock 107, 112) disposed on another electronic component, or may be used as the local clock for the electronic component. The early clock 204 provides an early clock signal 210 to a delay block 206 that represents the propagation delay between electronic components. As noted previously, sources of the delay include, but are not limited to, the propagation delay of cables or transmission lines connecting the components, the propagation delay of splitters and the propagation delay caused by electrical connectors.

The early clock signal input 210 to the delay block 206 provides a clock signal 207 to a second local clock on the next electronic component. As described more fully herein, the clock signal 207 is the midpoint clock signal of the delay path and is substantially synchronized to the input clock signal 205 to within the limits of a transfer function of the PDB 201. Moreover, the output clock signal 207 may be used in another apparatus in an electronic component to synchronize a local clock on a daisy chained electronic component, and so forth.

The clock signal 207 is split at the output of the delay block 206 and input to a second delay block 208. The second delay block 208 provides substantially the same propagation delay as the delay block 206. The second delay block 208 outputs a return signal 209 useful in synchronizing the input local clock signal 205 and the midpoint clock signal 207 in both phase and frequency. This synchronization is achieved by driving the early clock 204 to provide a signal 210 having substantially the same frequency as the input and midpoint clock signals 205, 207, respectively; and having a phase lead relative to the first local clock signal (e.g., signal 205) that is substantially the same as a phase lag of the return clock signal 209 to the first local clock signal (e.g., signal 205).

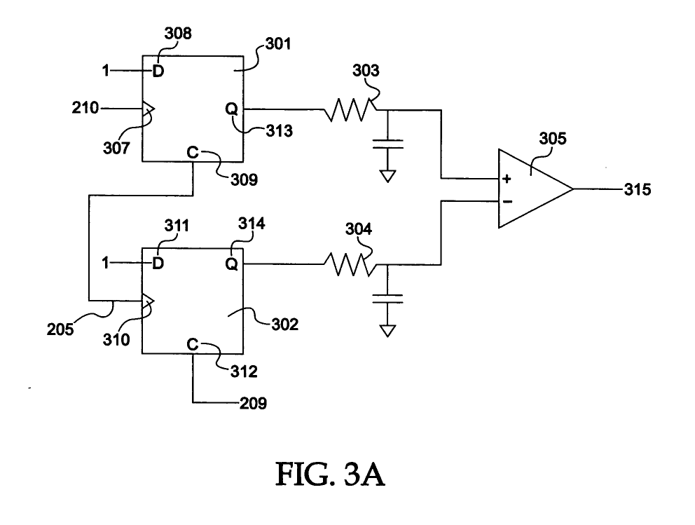

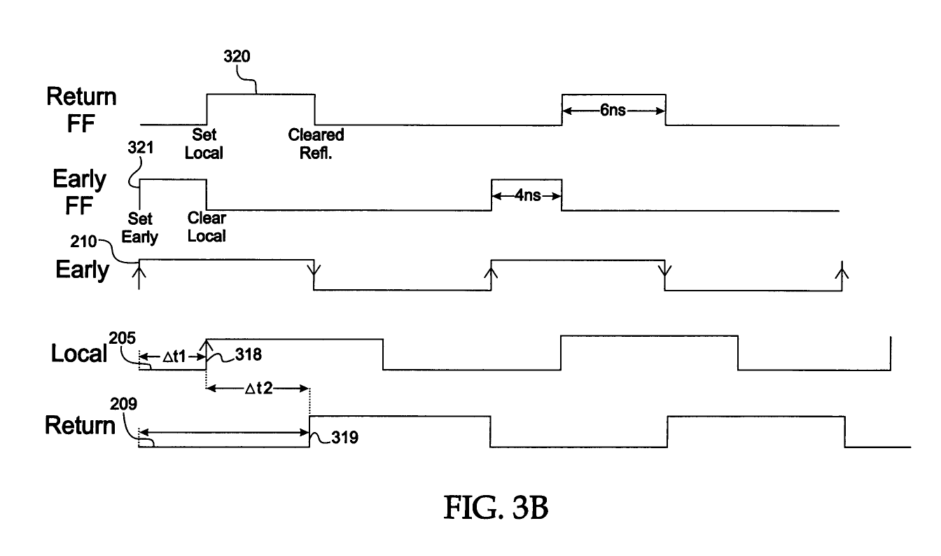

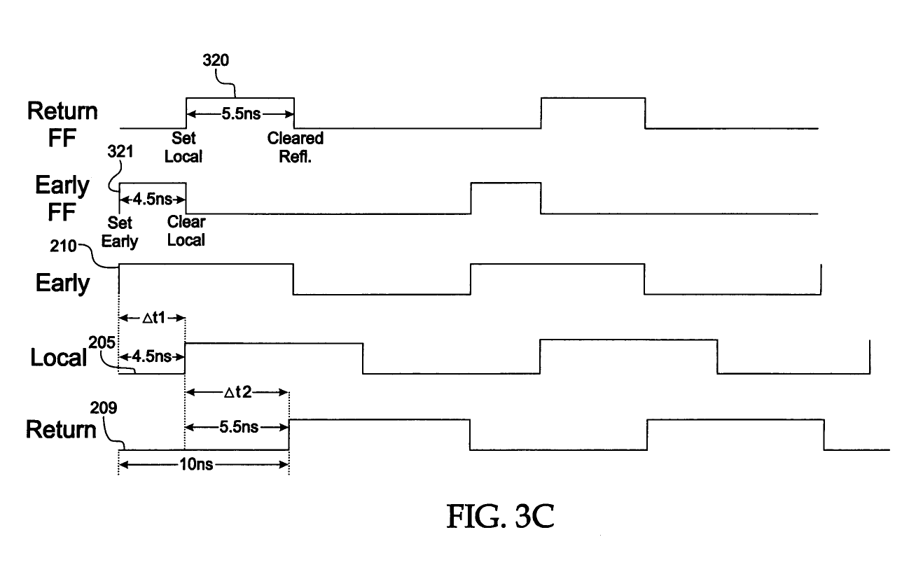

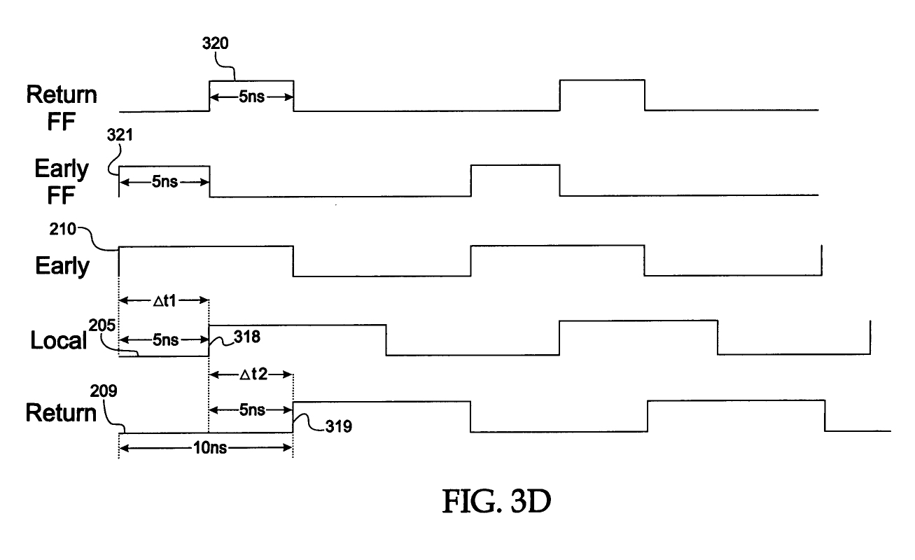

FIG. 3A is a simplified schematic diagram of a phase detector/balancer (PDB) circuit in accordance with an example embodiment. The PDB circuit includes a first logic device 301, a second logic device 302, a first RC filter 303 and a second RC filter 304. In a specific embodiment, the logic devices 301, 302 are D-flip flops. The outputs of the RC filters 303, 304 are the inputs to a difference amplifier 305. The output of the difference amplifier 305 constitutes the output of the PDB circuit 300 and is input to the loop filter 202, and ultimately drives the early clock 204.

The clock signal 210 from the early clock 204 is a clock input 307 of the first logic device 301 and a D input 308 is maintained as a digital ‘1.’ A clear input 309 receives the input clock signal 205. A Q output 313 is a digital ‘1’ at the rising edge of the early clock 204 and is cleared at the rising edge of the input signal 205. Thus, the Q output 313 is a pulse having a width representative of the delay between the local or midpoint clock signal to early clock.

In a daisy chain arrangement such as described in connection with the embodiment of FIG. 1, the input signal 205 may be a signal of a local clock 104, 117 or may be a midpoint signal 116, 119. Regardless if the signal is a local clock signal or a midpoint signal, the input signal 205 is a clock input 310 of the second logic device 302, and a D input 311 is maintained as a digital ‘1.’ The return signal 209 is a clear input 312. On the rising edge of the input signal 205 is a digital ‘1’ and the Q output 314 is a digital ‘1.’ At the rising edge of the return clock 209, the Q output 314 is cleared. Thus, the Q output is a pulse representative of the delay between the local or midpoint clock signal to the return clock signal.

When the phase delay between the local or midpoint clock signal clock and return signal is substantially the same as the phase lead of the early clock signal to the local or midpoint clock signal, the input signal 205 is substantially synchronized with the output signal 207. As such, the local clock signals 104, 107 are substantially synchronized with the midpoint clock signals at midpoints 116,119. In this case the output pulses of the Q outputs 313 and 314 are substantially the same and an output voltage 315 of the difference amplifier 305 is substantially zero. Notably, the integrator 203 translates this voltage into a voltage output 315 that drives the early clock at a suitable frequency to maintain the phase and frequency lock.

FIGS. 3B-3D are timing diagrams of a clock signals in a sequence of synchronizing clock functions of electronic components in accordance with an example embodiment. The synchronization sequence described in conjunction with FIGS. 3B-3D relates back to the PDB circuit 300.

FIG. 3B shows the timing diagram when the local/midpoint clock signals are not synchronized. Returning to FIG. 1, this means that the clock signal from the local clock 104 is not synchronized with the clock signal at the midpoint 116, for example. In the present illustration, early clock signal 210 leads the input clock signal 205 by a time (or phase) Δt1=4.0 ns; and the return clock signal 209 lags the input clock signal 205 by a time (or phase) Δt2=6.0 ns. Thus, the early clock-to-return clock signals have an initial time differential of Δt3=10 ns and the local/midpoint clock signals are not synchronized.

Ultimately, the sequence of adjusting the early clock 204 via the differential amplifier 305 results in Δt1=Δt2. At this point, rising edges of the early, input and return clock signals result in pulses at the Q outputs 313, 314 that are substantially the same and the differential amplifier 305 registers a zero output voltage. Because these pulses are representative of the phase/time lag and lead of the return and early clock relative to the input clock, the phase/time lag and lead are substantially the same, and the local or midpoint clock signals are synchronized.

The rising edge 317 of the early clock signal 210 sets the clock input 307 to a digital ‘1.’ After time Δt1 has passed, the local or midpoint input signal 205 has a rising edge 318, which sets the clock input 310 (as shown in Return Flip Flop timing diagram 320) and simultaneously clears (as shown in Early Flip-Flop timing diagram 321) the first logic device 301 via clear input 309, resulting in a pulse at the Q output 313 representative of the early-to-local clock time differential. After time Δt2 has passed, the rising edge 319 of the return signal clears the first logic device via clear input 312. A pulse is thus provided at the Q output 314 representative of the time differential between the local and reflected clock signals. As can be appreciated from the above description, the pulse from Q output 313 has a comparatively smaller width than the pulse from the Q output 314. The pulses from the Q outputs are converted to voltages by the RC circuits 303,304 and result in a non-zero (in this illustration negative) voltage at output 315.

The negative voltage at output 315 is provided from the PDB 201 to the loop filter 202, to the integrator 203 and the output of the integrator 203 is the input voltage to the early clock oscillator 204.

The filter 202 reduces the pulses from the logic devices 301, 302 to DC levels so that a difference voltage may be obtained in the difference amplifier 305. As is common in the design of PLL loop filters, the filter 202 also allows control of the loop response of the entire loop. This control is useful: if the loop response is too fast the loop will respond to noise and can oscillate; if the loop response is too slow, the loop may not respond quickly enough to compensate for the differential in the phase delay, will have an offset, or will not lock.

The integrator 203 allows the VCXO 204 to have a non-zero DC control input voltage when the difference amplifier output is substantially zero volts indicative of substantial clock synchronization between circuit boards. If it did not exist, there would always be some phase error.

The voltage input to the oscillator 204 drives the relative phase of the early clock 204 reducing the phase/time differential between the early clock-to-local/midpoint clock signal and the return signal-to-the local midpoint clock signal. Changing the control voltage to the oscillator 204 (VCXO) changes the instantaneous phase angle of the oscillator with respect to the master clock. Once the phase has been changed enough that the board to board delay is substantially zero, the control voltage provided to the oscillator 204 stops changing. In an embodiment, two VCXOs are provided. As the oscillator 204. When these VCXOs are in frequency lock, the control voltage to one of the VCXOs is changed slightly relative to the other in order to “slip” the phase into phase lock. Once the phase matches, there is no need to “slip” the phase and the control voltage returns to its quiescent value.

As shown in FIG. 3C, the phase of the early clock signal 210 is shifted and the relative phase of the early clock and local clock signals 210, 204 is smaller in magnitude than in the timing diagram of FIG. 3B. In particular, the phase adjustment results in Δt1 increased to 4.5 ns and Δt2 decreased to 5.5 ns. After time Δt1 has passed, the local or midpoint input signal 205 has a rising edge 318, which sets the clock input 310 (as shown in Return Flip Flop timing diagram 320) and simultaneously clears (as shown in Early Flip-Flop timing diagram 321) the first logic device 301 via clear input 309, resulting in a pulse at the Q output 313 representative of the early-to-local clock time differential.

After time Δt2 has passed, the rising edge 319 of the return signal clears the first logic device via clear input 312. A pulse is thus provided at the Q output 314 representative of the time differential between the local and reflected clock signals. As can be appreciated from the above description, the pulse from Q output 313 has a comparatively smaller width than the pulse from the Q output from the Q output 314. However, the difference in the pulse widths is reduced as a result of the shift in the relative phase of the clock signals. The pulses from the Q outputs are converted to voltages by the RC circuits 303,304 and result in a non-zero (in this illustration negative) voltage at output 315.

As described above, the negative voltage at output 315 is provided from the PDB 201 to the loop filter 202, to the integrator 203 and the output of the integrator 203 is the input voltage to the early clock oscillator 204. The voltage input to the oscillator 204 drives the relative phase of the early clock 204 reducing the phase/time differential between the early clock-to-local/midpoint clock signal and the return signal-to-the local midpoint clock signal.

FIG. 3D shows the result of the adjustment of the phase of the early clock until Δt1=6t2. After time Δt1 has passed, the local or midpoint input signal 205 has a rising edge 318, which sets the clock input 310 (as shown in Return Flip Flop timing diagram 320) and simultaneously clears (as shown in Early Flip-Flop timing diagram 321) the first logic device 301 via clear input 309, resulting in a pulse at the Q output 313 representative of the early-to-local clock time differential. After time Δt2 has passed, the rising edge 319 of the return signal clears the first logic device via clear input 312. A pulse is thus provided at the Q output 314 representative of the time differential between the local and reflected clock signals. However, because the phase lead of the early-to-local clock signal is substantially equal to the phase lag of the local-to-return clock signals, the pulse from Q output 313 has substantially the same width as the pulse from the Q output 314. As such a zero voltage is provided at output 315. In this case, there is no adjustment of the oscillator 204 and the local and midpoint clock signals are substantially synchronized.

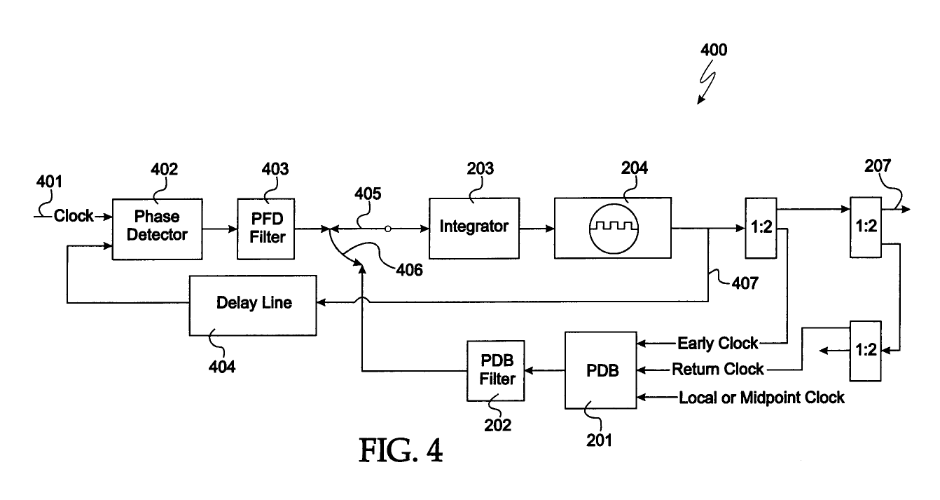

FIG. 4 is a simplified schematic block diagram of a synchronization apparatus 400 in accordance with an example embodiment. The apparatus shares certain common features with the embodiments described in connection with FIGS. 1-3B. These common features are not repeated to avoid obscuring the present description.

The apparatus includes an initial lock loop and an automatic lock loop. The automatic lock loop is very similar to the synchronization apparatus 200 described in connection FIG. 2. The initial lock loop includes a phase detector 402, a loop filter 403 and a delay line 404. A switch is provided to engage the initial lock loop in a first position 405 and to engage the automatic lock loop in a second position 406.

In the first position 405, initial lock is begun to synchronize initial synchronize an input clock signal 401 with the output signal 207, which is the midpoint clock signal provided from one circuit board to the next circuit board. The phase detector 402 and the loop filter 403 are known devices. The function of the integrator 203 and early clock 204 are as previously described. In order to initially synchronize the input signal 401 with the output signal, a delay block 404 is provided. This delay path provides a path length delay to the signal returned from the early clock 204 to the phase detector 402. The amount of path delay provided by the delay block 404 is from an initial estimate of the path delay between the first circuit board and the second circuit board (e.g. circuit boards 101, 102).

The initial lock provided by the initial lock loop provides a coarse lock for the system. After the input signal 401 is substantially synchronized with the output signal 407 at the midpoint, the switch is changed to a second position 406 at which the automatic lock loop is engaged and the synchronization of the input (local) signal to the midpoint signal is carried out in a manner described previously in connection with FIGS. 1-3D.

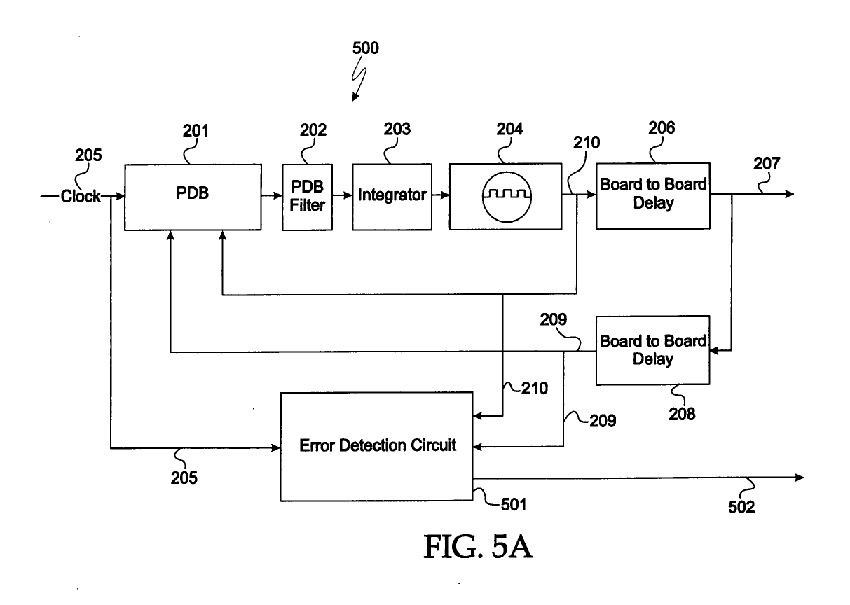

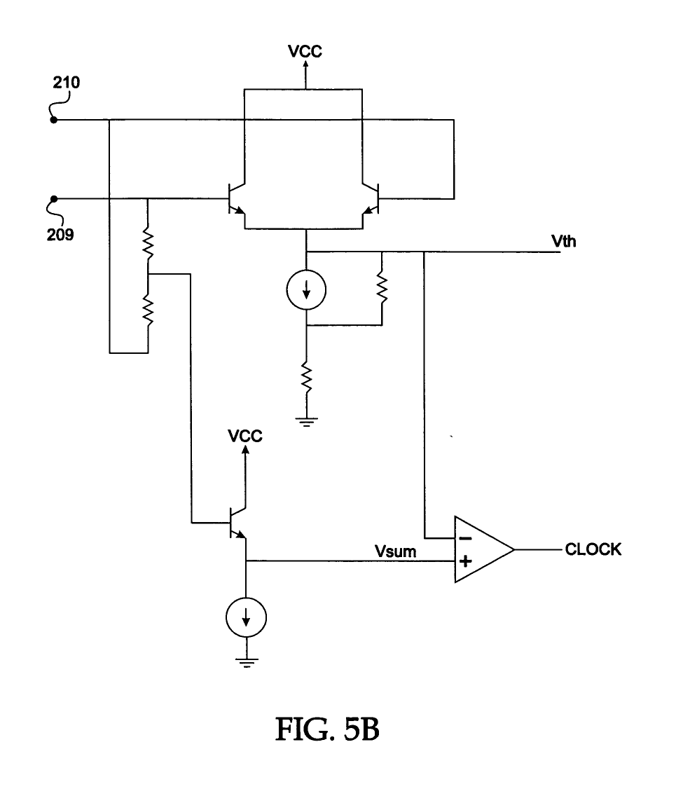

FIG. 5A is a simplified block diagram of a synchronization apparatus 500 in accordance with an example embodiment. The apparatus shares certain common features with the embodiments described in connection with FIGS. 1-3B. These common features are not repeated to avoid obscuring the present description.

The apparatus includes an automatic lock loop comprising the PDB 201, the PDB filter 202, the integrator 203, the oscillator 204 and board-to-board delays 206, 208.

The output 207 is provided to the next circuit board as described previously. Signals 209 and 210 are provided to the PDB 201. In addition, signals 205, 209 and 210 are provided to an error detection circuit 501, which provides an output error detection signal 502 as shown.

FIG. 5B is a simplified schematic diagram of the error detection circuit according to an example embodiment.

As is known, digital signals are often transmitted in analog form with pulses representing the binary data. The analog signals are often sampled at discrete time intervals to garner the binary data. While the sampling of the pulses is usefully at the center of the pulses, jitter or skew can result in the deviation of the pulse. The deviation of the pulse can result in sampling at the incorrect position on the pulse, resulting in bit error.

As is also known, jitter may result from many sources and may be bounded or random. The former may result from system and data-dependent mechanisms and the latter may result from random noise. As can be appreciated, the measure of the affect of jitter on signal (bit) error is useful. Measurement systems often include a measure of the bit error rate.

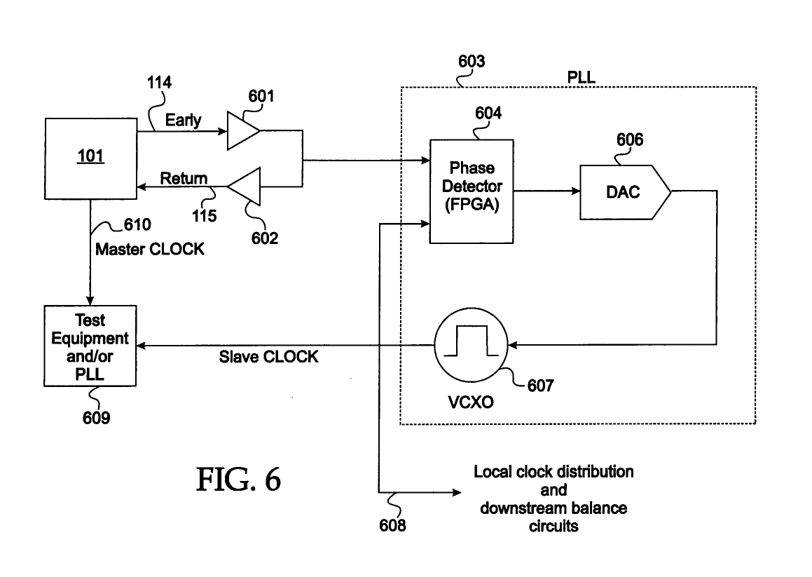

FIG. 6 is a simplified block diagram of an apparatus 600 useful in calibration of a jitter or skew measurement apparatus in accordance with an example embodiment. In an embodiment, the apparatus 600 receives the early clock signal 114 from the first (master) circuit board 101 at an amplifier 601 and provides the signal from the midpoint 116 to a PLL 603. The return clock signal 115 is provided to the first circuit board 101 after amplification by a second amplifier 602.

The PLL 603 includes a phase detector (PD) 604, which is instantiated in a field programmable gate array (FPGA) in a specific embodiment. The PD 604 determines the phase difference between the clock signal at the midpoint 116, which functions as the local clock as described previously, and a local clock signal 608 from other circuits (e.g., boards 102, 103).

The output of the PD 604 represents the phase differential between the local clock from the midpoint 116 and the local clock signal 608 from other boards. This differential may be due to jitter. A digital-to-analog converter DAC 606 receives the output from the PD 604 and provides a voltage signal to a VCXO 607. In the event that the phase differential is non-zero, the phase of the oscillator 607 is altered in response to the voltage signal from the DAC 606. The output of the VCXO 607 is the shifted slave (or local) clock signal and is provided to a calibration block 609, which comprises test equipment, or a PLL, or both. The master clock signal 610 is also applied to the calibration block 609.

From the test equipment, or the PLL, or both, the phase and frequency difference between the master and local clock can be measured. This allows the master clock to be adjusted to calibrate the master and slave clocks to account for jitter.

In accordance with example embodiments, an apparatus for and method of synchronizing clocks are described. The apparatus and method may be used in a network, such as a local area network (LAN). One of ordinary skill in the art appreciates that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

1. An apparatus, comprising:
an early clock that provides an early clock signal having a rising edge that leads a rising edge of a clock signal by a duration of time; and a
a return clock signal having a rising edge that lags the rising edge of the clock signal by substantially the duration of time.

2. An apparatus as recited in claim 1, wherein a first local clock provides the clock signal and the first local clock and the early clock are disposed on a first electronic component and the first circuit board is connected to a second electronic component.

3. An apparatus as recited in claim 2, further comprising a delay path having a midpoint and the clock signal is a midpoint clock signal at the midpoint of the delay path.

4. An apparatus as recited in claim 3, wherein the first electronic component is a circuit board and the second electronic component is a circuit board.

5. An apparatus as recited in claim 4, further comprising:
a third circuit board connected to the second circuit board and a second delay path between the second circuit board and the third circuit board;
a second early clock disposed on the second circuit board that provides a second early clock signal; and
a second local clock disposed on the second circuit board that provides a second clock signal, wherein the second early clock signal has a rising edge that leads a rising edge of the second clock signal by the duration of time and a second return clock signal from the third circuit board has a rising edge that lags a rising edge of the second clock signal by the duration of time.

6. An apparatus as recited in claim 1, further comprising:
an initial lock loop, comprising:
a phase detector connected to the early clock; and
a delay line having, which receives an output of the early clock and provides an input to the phase detector.

7. An apparatus as recited in claim 1, further comprising:
an automated lock loop, comprising:
a phase detector/balancer (PDB) circuit adapted to receive the return signal and the early clock signal, wherein the PDB circuit alters an input to the early clock until the lead of the rising edge of the first local clock and the lag of the rising edge of the return clock signal are substantially the same.

8. An apparatus as recited in claim 7, wherein the phase detector balancer further comprises:
a first logic block and a second logic block, each having an output connected to a difference amplifier, and the difference amplifier provides an output to the early clock that alters the lead of the early clock.

9. An apparatus as recited in claim 1, further comprising:
a phase lock loop (PLL) connected to a midpoint of a delay path; and
a calibration block adapted to receive an output of the PLL and an output of the clock signal, wherein the calibration block adjusts the clock signal to compensate for jitter.

10. A method for synchronizing clock functions of electronic components, the method comprising:
providing a clock signal;
providing an early clock signal;
comparing a lead time of a rising edge of the early clock signal to a rising edge of the clock signal to a lag time of a rising edge of a return clock signal to the rising edge of the clock signal; and, if the lead time does not substantially equal the lag time, altering the early clock signal until the lead time and lag time are substantially equal.

11. A method as recited in claim 10, providing a delay path having a midpoint, wherein a clock signal at the midpoint is substantially synchronized with the clock signal.

12. A method as recited in claim 10, wherein the altering further comprises changing an input to the early clock until the lead time and lag time are substantially equal.

13. A method as recited in claim 12, wherein the input is an output of a phase detector balancer (PDB) circuit.

14. A measurement apparatus, comprising:
an early clock that provides an early clock signal having a rising edge that leads a rising edge of a clock signal by a duration of time; and a
a return clock signal having a rising edge that lags the rising edge of the clock signal by substantially the duration of time.

15. A measurement apparatus as recited in claim 14, wherein a first local clock provides the clock signal and the first local clock and the early clock are disposed on a first electronic component and the first circuit board is connected to a second electronic component.

16. A measurement apparatus as recited in claim 15, further comprising a delay path having a midpoint and the clock signal is a midpoint clock signal at the midpoint of the delay path.

17. A measurement apparatus as recited in claim 16, wherein the first electronic component is a circuit board and the second electronic component is a circuit board.

18. A measurement apparatus as recited in claim 17, further comprising:
a third circuit board connected to the second circuit board and a second delay path between the second circuit board and the third circuit board;
a second early clock disposed on the second circuit board that provides a second early clock signal; and
a second local clock disposed on the second circuit board that provides a second clock signal, wherein the second early clock signal has a rising edge that leads a rising edge of the second clock signal by the duration of time and a second return clock signal from the third circuit board has a rising edge that lags a rising edge of the second clock signal by the duration of time.

19. A measurement apparatus as recited in claim 14, further comprising:
an automated lock loop, comprising:
a phase detector/balancer (PDB) circuit adapted to receive the return signal and the early clock signal, wherein the PDB circuit alters an input to the early clock until the lead of the rising edge of the first local clock and the lag of the rising edge of the return clock signal are substantially the same.
